(19) United States
(12) Patent Application Publication
(10) Pub. No.: US 2026/0122884 A1
(43) Pub. Date: Apr. 30, 2026

(54) SEMICONDUCTOR MEMORY DEVICE CAPABLE OF MITIGATING ROW HAMMER EFFECT

(71) Applicant: Korea University Research and Business Foundation, Seoul (KR)

(72) Inventors: CHANG HWAN SHIN, Seoul (KR); JIYEONG YOON, Seoul (KR); SEOKCHAN YOON, Seongnam-si (KR)

(21) Appl. No.: 19/003,771

(22) Filed: Dec. 27, 2024

(30) Foreign Application Priority Data
Aug. 7, 2024 (KR) 10-2024-0105715

(51) Int. Cl. H10B 12/00

(52) U.S. Cl. CPC H10B 12/34; H10B 12/053

(57) ABSTRACT

The present disclosure relates to a structure of a semiconductor memory device capable of mitigating the row hammer effect that occurs by repeated access to word lines. A semiconductor memory device according to an embodiment of the present disclosure includes a substrate, an element isolation film formed to extend in a vertical direction in the substrate, and a first gate structure formed to extend in the vertical direction in the element isolation film, and a second gate structure formed to be spaced apart from the element isolation film in a horizontal direction and extend in the vertical direction in the substrate, wherein a hollow pocket is formed below the first gate structure in the element isolation film.

### CROSS-REFERENCE TO RELATED APPLICATION

This application is based on and claims the benefit of priority to Korean Patent Application No. 10-2024-0105715, filed Aug. 7, 2024, the aforementioned priority application being hereby incorporated by reference in its entirety.

### TECHNICAL FIELD

The present disclosure relates to a structure of a semiconductor memory device capable of mitigating the row hammer effect that occurs by repeated access to word lines.

### BACKGROUND

Dynamic Random Access Memory (DRAM) is a typical semiconductor memory device for data storage, which stores data using memory cells (hereinafter referred to as cells) consisting of one transistor and one capacitor. Such DRAM must continuously recharge a charge to maintain data stored in the capacitor, and a refresh operation is essential for this.

Meanwhile, as a physical distance between cells becomes shorter according to the advancement of DRAM process technology, reliability problems of the device are occurring due to interference between cells. Row hammer is one of the interference effects, which is an effect in which a data error occurs in another adjacent cell when a specific cell is repeatedly accessed. This causes data loss and requires very frequent refresh operations to prevent data loss, resulting in increased power consumption of DRAM.

Recently, software solutions, which prevent a specific cell from being repeatedly accessed, have been developed to prevent this row hammer effect, but there is still no way to fundamentally solve the row hammer effect.

### SUMMARY

One of the objects of the present disclosure is mitigating the row hammer effect that occurs in DRAM.

The objects of the present disclosure are not limited to the objects mentioned above, and other objects and advantages of the present disclosure, not mentioned above, can be understood by the following description and will be more clearly understood by the embodiments of the present disclosure. In addition, it will be easily understood that the objects and advantages of the present disclosure can be realized by the features and combinations thereof disclosed in the claims.

According to one embodiment of the present disclosure, there is provided a semiconductor memory device according to an embodiment of the present disclosure to achieve the above object includes a substrate, an element isolation film formed to extend in a vertical direction in the substrate, a first gate structure formed to extend in the vertical direction in the element isolation film, and a second gate structure formed to be spaced apart from the element isolation film in a horizontal direction and extend in the vertical direction in the substrate, wherein a hollow pocket is formed below the first gate structure in the element isolation film.

### BRIEF DESCRIPTION OF THE DRAWINGS

Embodiments will be more clearly understood from the following detailed description taken in conjunction with the accompanying drawings in which:

FIG. 1 is a diagram illustrating a layout of a DRAM to which a buried channel array transistor (BCAT) structure is applied.

FIG. 2 is a cross-sectional view taken along A-A′ of the layout of the DRAM illustrated in FIG. 1.

FIG. 3 is a contour map illustrating an intensity of an electric field appearing in the cross section illustrated in FIG. 2 when a gate of a word line (PWLA) is activated.

FIG. 4 is a graph illustrating the intensity of the electric field in the B-B′ section of FIG. 3.

FIG. 5 is a diagram illustrating a cross section of a semiconductor memory device according to an embodiment of the present disclosure.

FIG. 6 is a diagram illustrating an intensity of an electric field appearing in the cross section illustrated in FIG. 5 when the gate of the word line (PWLA) is activated.

FIG. 7 is a graph illustrating the intensity of the electric field in the B-B′ section of FIG. 6 according to the presence or absence of a pocket.

FIG. 8 is a contour map illustrating a SRH (Shockley-Read-Hall) recombination rate according to the presence or absence of a pocket when the semiconductor memory device according to an embodiment of the present disclosure is viewed on the Y-Z plane.

FIG. 9 is a graph illustrating the SRH recombination rate according to the presence or absence of a pocket in the C-C′ section of FIG. 8.

FIG. 10 is a contour map illustrating a current density according to the presence or absence of a pocket when the gate of the word line (PWLA) is activated.

FIG. 11 is a graph comparing a voltage of a storage node according to the presence or absence of a pocket when the gate of the word line (PWLA) is activated.

FIG. 12 is a diagram schematically illustrating a process of forming a pocket.

FIG. 13 is a diagram illustrating a process of manufacturing a pocket according to an embodiment.

### DETAILED DESCRIPTION

The above objects, features, and advantages will be described in detail hereinafter with reference to the accompanying drawings, whereby those skilled in the art to which the present disclosure pertains will be able to easily implement the technical idea of the present disclosure. In describing the present disclosure, a detailed description of well-known techniques related to the present disclosure will be omitted if it is determined that the gist of the present disclosure may be unnecessarily obscured. Hereinafter, exemplary embodiments of the present disclosure will be described in detail with reference to the accompanying drawings. In the drawings, the same reference numerals are used to refer to the same or similar elements.

In this specification, it is understood that terms such as “a first,” “a second,” etc. are used to describe various elements, but these elements are not limited by these terms. These terms are merely used to distinguish one element from another, and unless otherwise specifically described, a first element may be a second element.

Further, in this specification, it is understood that any configuration being placed “on (or under)” or “above (or below)” an element, or at an upper portion (or lower portion) means that the configuration being in contact with an upper surface (or lower surface) of the element, and also that the configuration being disposed over an upper surface (or lower surface) of the element with another element interposed therebetween.

Furthermore, when it is described in this specification that an element is “connected,” “coupled,” or “contacted” to another element, the elements may be directly connected or contacted to each other, or the elements may be connected, coupled, or contacted to each other via another element or with another element interposed therebetween.

In addition, the singular expressions used in this specification include the plural expressions unless clearly otherwise described in the context.

In the present disclosure, it is understood that terms such as “configured” or “include” should not be construed as necessarily including all of the various elements or various steps described in the specification, and it should be construed that some of these elements or steps may not be included, or additional elements or steps may be further included.

In addition, in this specification, it is understood that when “A and/or B” is used, this means A, B, or A and B unless otherwise described, and when “C to D” is used, this means C or more and D or less unless otherwise described.

The present disclosure relates to the structure of a semiconductor memory device capable of mitigating the row hammer effect that occurs by repeated access to word lines.

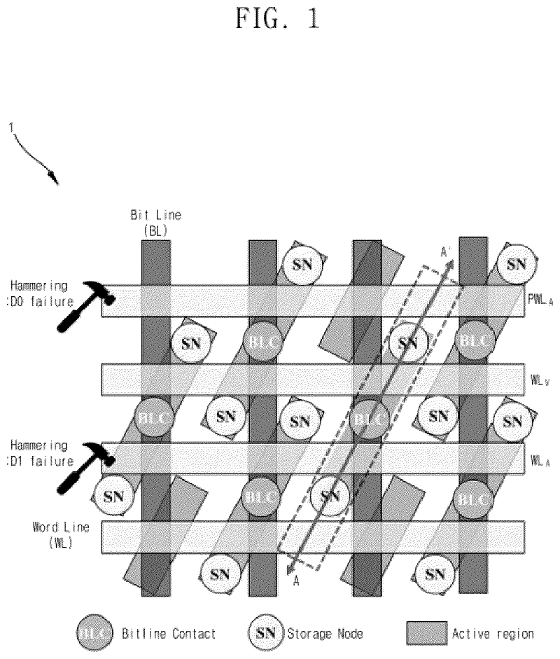

Before describing the structure of the present disclosure, the row hammer effect to be improved according to the present disclosure will be described with reference to FIGS. 1 to 4.

FIG. 1 is a diagram illustrating a layout of a DRAM to which a buried channel array transistor (BCAT) structure is applied.

Referring to FIG. 1, the semiconductor memory device can be implemented as a DRAM 1 to which a buried channel array transistor structure in which two memory cells (hereinafter referred to as cells) share one bit line (BL) is applied.

Specifically, the semiconductor memory device includes a plurality of bit lines (BL), a plurality of word lines (WL) intersecting each bit line (BL), and a plurality of bit line contacts (BLC) where each bit line (BL) intersects an active region (AR).

The plurality of word lines (WL) can be spaced apart from each other and extend in a horizontal direction, and can function as gate electrodes. On the other hand, the plurality of bit lines (BL) can be spaced apart from each other and extend in a vertical direction, and accordingly, each word line (WL) and bit line (BL) can be arranged to intersect each other vertically.

On the other hand, the plurality of active regions (AR) can extend in a direction inclined (that is, obliquely) to each of the word line (WL) and the bit line (BL) when viewed in a top view. Each active region (AR) can be parallel to each other, and the end of each active region (AR) arranged side by side in a longitudinal direction can be arranged adjacent to the end of other active regions (AR).

The active region (AR) can include impurities to function as a source and drain. Specifically, the center of the active region (AR) can be connected to the bit line (BL) via the bit line contact (BLC). In addition, the end of the active region (AR) can be connected to a storage node (SN) via a buried contact (not shown). Accordingly, the center and end of the active region (AR) can constitute a source or drain region, respectively.

On the other hand, as a physical distance between cells becomes shorter according to the advancement of DRAM process technology, the row hammer effect occurs by interference between cells. The row hammer effect is an effect in which a data error occurs in another adjacent cell when a specific cell is repeatedly accessed, which causes data loss and requires frequent refresh operations, thereby increasing the power consumption of DRAM.

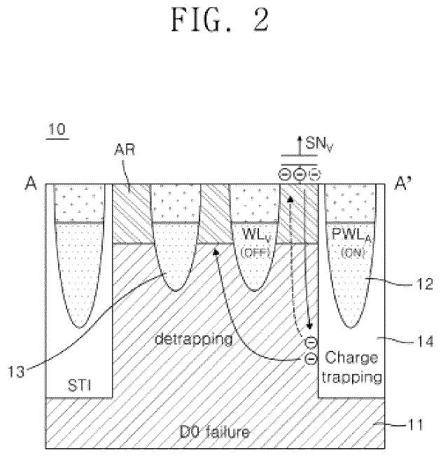

Hereinafter, a DO error (DO failure), which is an example of the row hammer effect, will be described with reference to FIGS. 2 to 4.

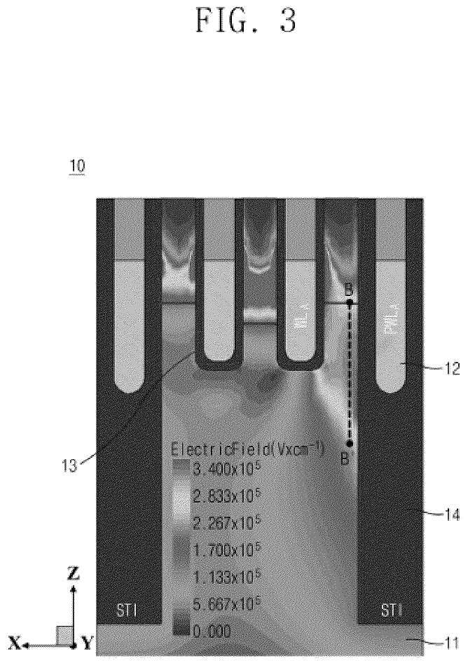

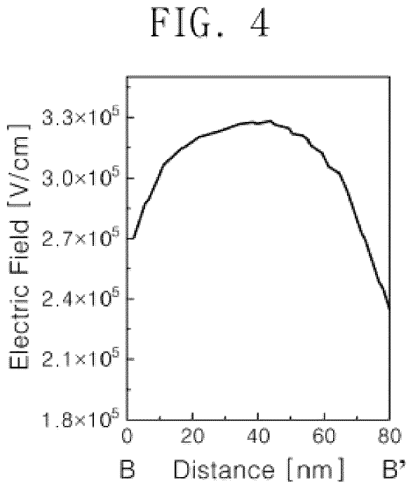

FIG. 2 is a cross-sectional view taken along A-A′ of the layout of the DRAM illustrated in FIG. 1. FIG. 3 is a contour map illustrating the intensity of an electric field appearing in the cross section illustrated in FIG. 2 when the gate of the word line (PWLA) is activated, and FIG. 4 is a graph illustrating the intensity of the electric field in the B-B′ section of FIG. 3.

Referring to FIGS. 1 and 2 together, when a passing word line (PWLA) 12 passing through an element isolation region (isolation area) adjacent to the active region (AR) is activated (ON), the electrons stored in the storage node (SN) of the adjacent victim cell are trapped at an interface between a substrate 11 and an element isolation film 14 such as a STI (Shallow Trench Isolation) structure.

After that, when the passing word line 12 is deactivated, the electrons should return to their original position, that is, the storage node (SN), but some electrons do not return to the storage node (SN) and move toward the bit line (BL). When the passing word line 12 is continuously accessed, that is, when the activation/deactivation operation is repeated, the number of electrons stored in the storage node (SN) gradually decreases, and a voltage (SNV) of the storage node (SN) increases. As a result, an error occurs in which data ‘0’ stored in the storage node (SN) is changed to ‘1.’

Referring to FIGS. 3 and 4 together, the reason that electrons do not return to the storage node (SN) and move to the bit line (BL) is that when the passing word line (PWLA) 12 is activated, a strong electric field formed between the substrate 11 and the element isolation film 14 pushes electrons toward the bit line (BL), and according to the present disclosure, it is possible to improve the row hammer effect by weakening the intensity of this electric field.

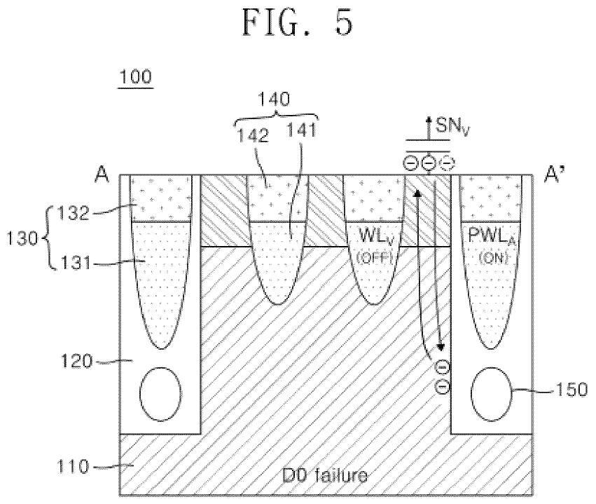

Hereinafter, the semiconductor memory device according to an embodiment of the present disclosure will be described in detail with reference to FIGS. 5 to 14.

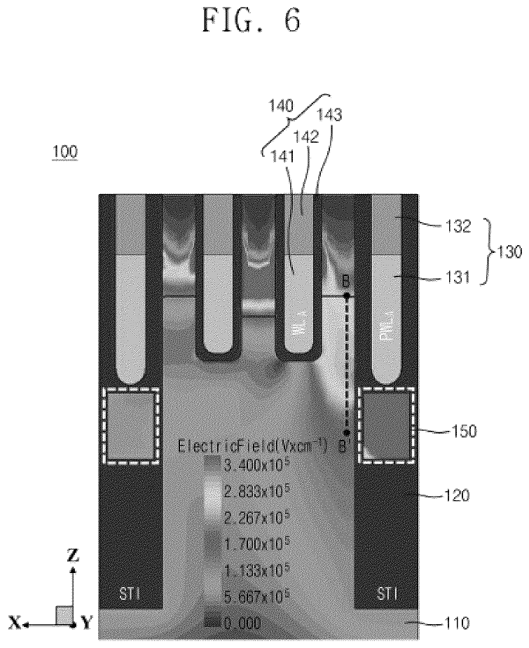

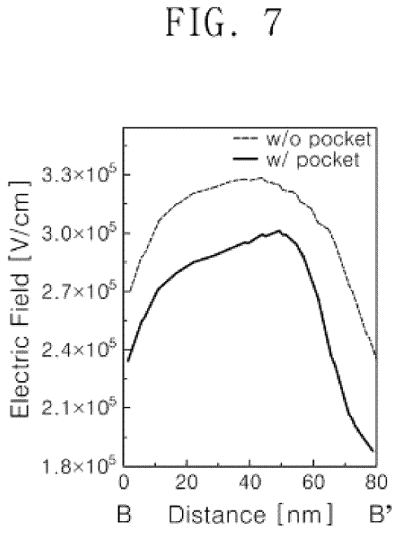

FIG. 5 is a diagram illustrating a cross section of a semiconductor memory device according to an embodiment of the present disclosure, and FIG. 6 is a diagram illustrating the intensity of an electric field appearing in the cross section illustrated in FIG. 5 when the gate of the word line (PWLA) is activated. In addition, FIG. 7 is a graph illustrating the intensity of the electric field in the B-B′ section of FIG. 6 according to the presence or absence of a pocket.

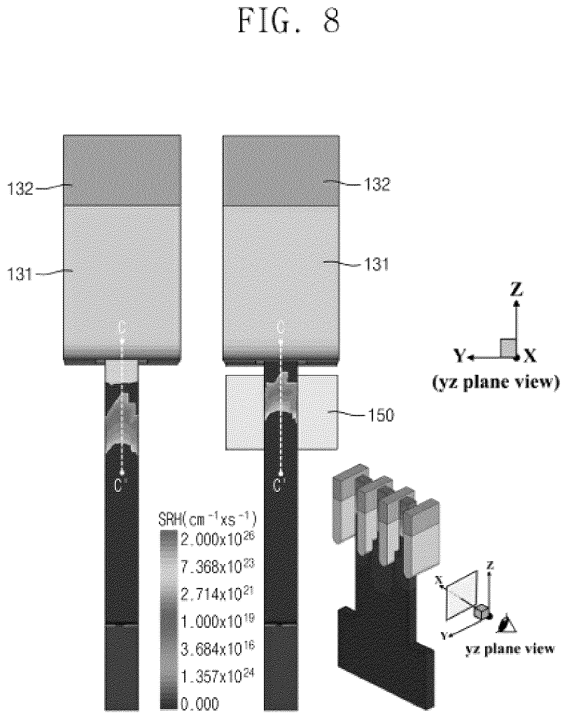

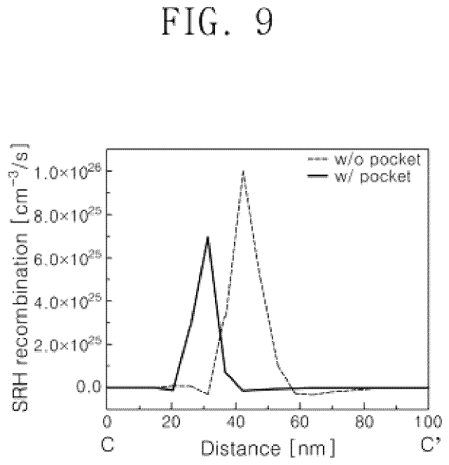

FIG. 8 is a contour map illustrating the SRH (Shockley-Read-Hall) recombination rate according to the presence or absence of a pocket when the semiconductor memory device according to an embodiment of the present disclosure is viewed on the Y-Z plane, and FIG. 9 is a graph illustrating the SRH recombination rate according to the presence or absence of a pocket in the C-C′ section of FIG. 8.

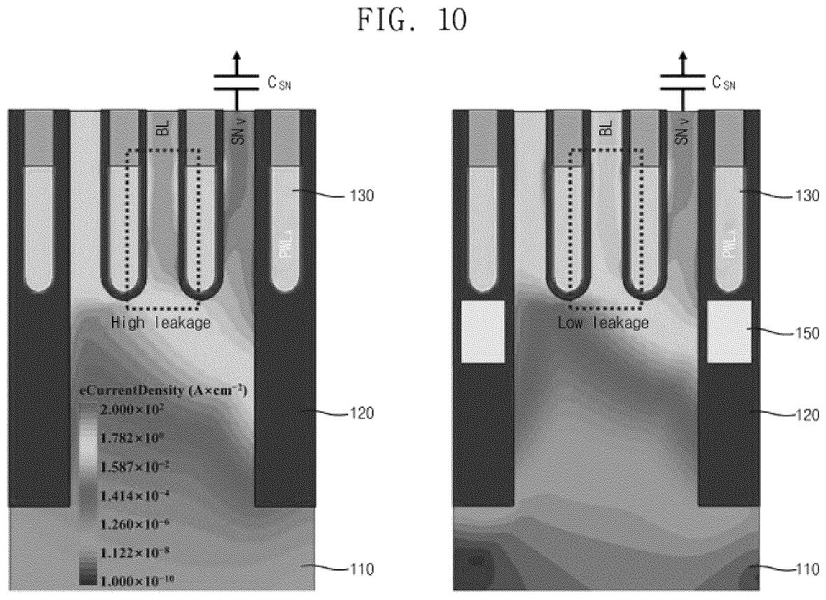

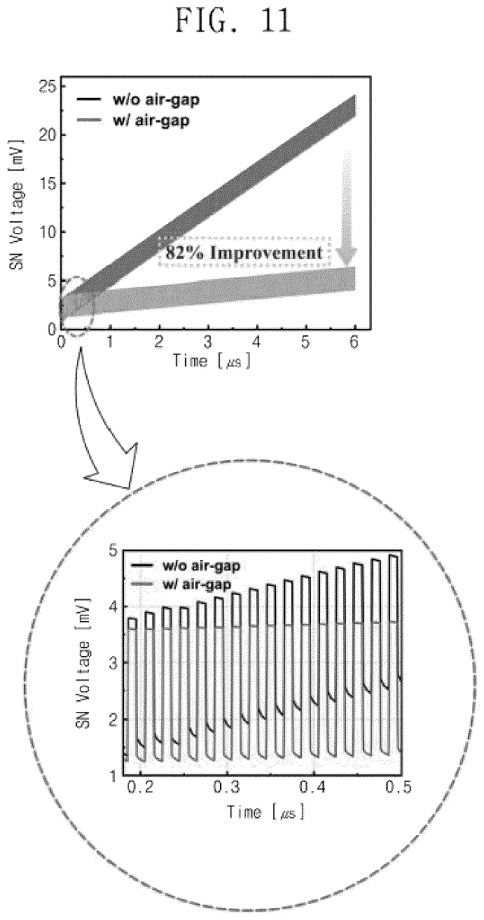

FIG. 10 is a contour map illustrating the current density according to the presence or absence of a pocket when the gate of the word line (PWLA) is activated, and FIG. 11 is a graph comparing the voltage of the storage node according to the presence or absence of a pocket when the gate of the word line (PWLA) is activated.

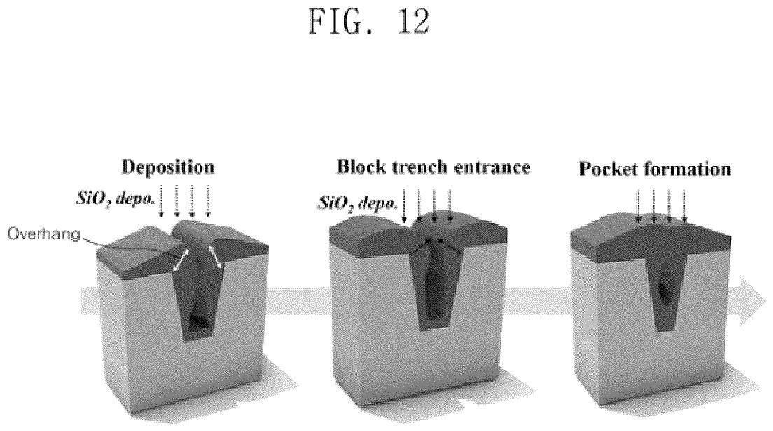

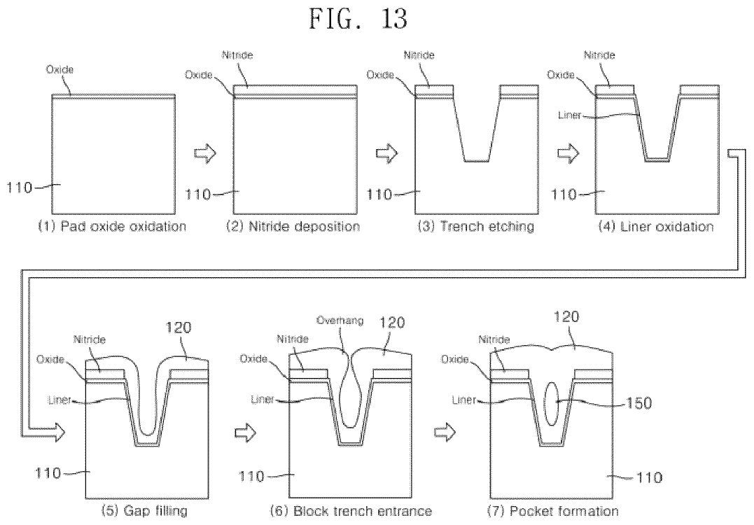

FIG. 12 is a diagram schematically illustrating the process of forming a pocket, and FIG. 13 is a diagram illustrating a process of manufacturing a pocket according to an embodiment.

It should be understood that a semiconductor memory device 100 of the present disclosure described below can be applied to DRAM 1 having various structures and types in addition to the DRAM (1) to which the buried channel array transistor structure illustrated in FIG. 1 is applied.

Referring to FIG. 5, the semiconductor memory device 100 according to an embodiment of the present disclosure may include a substrate 110, an element isolation film 120, a first gate structure 130, a second gate structure 140, and a pocket 150. However, the semiconductor memory device 100 illustrated in FIG. 5 is according to an embodiment, and some elements may be added or changed as necessary.

The substrate 110 is a silicon-based substrate, and may include at least one of materials such as bulk silicon, SOI (silicon-on-insulator), silicon germanium, SGOI (silicon germanium on insulator), indium antimonide, lead telluride compound, indium arsenide, indium phosphide, gallium arsenide, or gallium antimonide.

The element isolation film 120 can be formed to extend in a vertical direction in the substrate 110. Here, the vertical direction does not mean a specific direction, but is preferably interpreted as a longitudinal direction of the element isolation film 120.

The element isolation film 120 may be made of a single or a plurality of insulating materials, and may be made of, for example, silicon oxide (SiO₂). On the other hand, the element isolation film 120 may be formed in the STI (Shallow Trench Isolation) structure in order to have high element isolation characteristics.

The first gate structure 130 can be formed to extend in the vertical direction in the element isolation film 120, that is, the same direction as the longitudinal direction of the element isolation film 120. For this, the first gate structure 130 can be embedded in the element isolation film 120. At this time, the first gate structure 130 may include a first gate electrode 131 and a first gate capping pattern 132 for insulating and protecting the first gate electrode 131. In addition to this, it is understood that the first gate structure 130 may further include a gate insulating film (not shown) having a high dielectric constant that surrounds an outer surface of the first gate electrode 131.

The first gate electrode 131 may be the passing word line (PWLA) described with reference to FIGS. 1 and 2, and may include a conductive metal oxide, a conductive metal nitride, a conductive metal oxynitride, and the like.

The first gate capping pattern 132 may be made of a low dielectric constant material, and may include at least one of materials such as polysilicon, silicon nitride (SiN), silicon oxynitride (SiON), silicon oxide (SiO₂), silicon carbonitride (SiCN), or silicon oxycarbonitride (SiOCN).

On the other hand, the second gate structure 140 can be formed to be spaced apart from the element isolation film 120 in the horizontal direction and extend vertically in the substrate 110. In other words, the second gate structure 140 can be formed to extend in the same direction as the longitudinal direction of the element isolation film 120 and the first gate structure 130, and can be formed to be spaced apart from the element isolation film 120 in the horizontal direction so that the second gate structure 140 is embedded in the substrate 110 outside the element isolation film 120.

The second gate structure 140 may also include a second gate electrode 141 and a second gate capping pattern 142 for insulating and protecting the second gate electrode 141, and may further include a gate insulating film 143. Here, the second gate electrode 141 may be a word line (WL) in a cell to be damaged by the passing word line PWLA.

Since a material constituting the second gate electrode 141 and the second gate capping pattern 142 is the same as the material constituting the first gate electrode 131 and the first gate capping pattern 132 described above, the description of the constituent material is will be omitted.

Referring to FIG. 5 again, the semiconductor memory device 100 according to an embodiment of the present disclosure may further include a hollow pocket 150 formed below the second gate structure 140 in the element isolation film 120. This pocket 150 may be formed in a form surrounded by the element isolation film 120 below the first gate structure (130), specifically, the passing word line (PWLA) of the DRAM. That is, the pocket 150 can be formed to be surrounded by the material constituting the element isolation film 120, in a state of not being in contact with an interface of the element isolation film 120.

On the other hand, the hollow pocket 150 can be filled with a material different from the element isolation film 120. However, the present disclosure introduces the pocket 150 to reduce the intensity of an electric field formed between the substrate 110 and the element isolation film 120. Thus, it may be desirable that the material filled in the pocket 150 has a lower dielectric constant than the element isolation film 120, and such a material may be, for example, a low-k dielectric having a lower dielectric constant than silicon oxide (SiO₂).

It may be more desirable that the pocket 150 is filled with air, which has the lowest dielectric constant, and its effect will be described below assuming that the hollow pocket 150 is filled with air.

Referring to FIGS. 6 and 7 together, it is understood that the semiconductor memory device 100 of the present disclosure includes the pocket 150, so that when the passing word line (PWLA), specifically the first gate electrode 131, is activated (ON), the intensity of an electric field formed between the substrate 110 and the element isolation film 120 is significantly reduced as compared to the structure (that is, structure not including the pocket 150) shown in FIG. 3. Accordingly, the electrons trapped at the interface of the substrate 110 and the element isolation film 120 can easily return to the storage node (SN) when the passing word line (PWLA) is deactivated.

In addition, referring to FIGS. 8 and 9 together, it is understood that the semiconductor memory device 100 of the present disclosure includes the pocket 150, so that when the passing word line (PWLA) is activated (ON), the SRH (Shockley-Read-Hall) recombination rate is significantly reduced as compared to the structure without the pocket 150. This means that the electric field generated in the structure including the pocket 150 captures fewer electrons than the electric field generated in the structure without the pocket 150. Accordingly, the electrons trapped at the interface of the substrate 110 and the element isolation film 120 can easily return to the storage node (SN) when the passing word line (PWLA) is deactivated.

In addition, referring to FIG. 10, it is understood that the semiconductor memory device 100 of the present disclosure includes the pocket 150, so that the current density below the bit line (BL) is significantly reduced as compared to the structure without the pocket 150 at the point in time when the passing word line (PWLA) is deactivated (ON). This means that the amount of electrons leaking to the bit line (BL) in the structure including the pocket 150 is lower than the amount of leakage in the structure without the pocket 150, and the electrons trapped at the interface of the element isolation film 120 return to the storage node (SN).

Referring to FIG. 11, it is understood that in the structure that does not include the pocket 150, a storage node voltage (SNv) increases rapidly according to the repeated activation/deactivation of the passing word line (PWLA), whereas in the structure of the present disclosure that includes the pocket 150, a storage node voltage (SNv) increases very gradually, and the voltage reduction effect of 82% occurs as compared to the structure without the pocket 150 at the point in time when the passing word line (PWLA) is operated for 6 μs.

As described above, according to the present disclosure, it is possible to prevent a data error or loss such as the DO error by mitigating the row hammer effect that occurs in the DRAM 1. In addition, according to the present disclosure, it is possible to reduce the frequency of refresh operations by mitigating the row hammer effect that occurs in the DRAM 1, and thus to significantly reduce the power consumption of the DRAM 1.

Hereinafter, the formation process of the pocket 150 will be described.

Referring to FIG. 12, the pocket 150 can be formed inside a trench by blocking an entrance of the trench before the trench is completely filled, in the process of depositing the element isolation film 120 on the trench formed in the substrate 110.

Referring to FIG. 13 for a more specific explanation, the pocket 150 can be formed by forming an oxide film, for example, a silicon oxide (SiO₂) film, on the substrate 110 (STEP 1. Pad oxide oxidation), depositing nitride on the oxide film to protect the oxide film (STEP 2. Nitride deposition), etching the substrate 110 to form a trench (STEP 3. Trench etching), forming a liner oxide film to repair a damage caused when etching (STEP 4. Liner oxidation), and filling the trench with an oxide constituting the element isolation film 120 through a process such as HDP-CVD (high-density plasma chemical vapor deposition) (STEP 5. Gap filling).

At this time, in (STEP 5. Gap filling), overhang regions may be formed at both ends of the entrance of the trench due to a high deposition rate. Here, the pocket 150 can be formed in the element isolation film 120 in a hollow form in (STEP 7. Pocket formation), by depositing oxide (the material constituting the element isolation film 120) on the trench until the overhang regions meet while the inside of the trench is not completely filled (STEP 6. Block trench entrance).

According to present disclosure, it is possible to prevent a data error or loss such as the DO error by mitigating the row hammer effect that occurs in DRAM.

In addition, according to the present disclosure, it is possible to reduce the frequency of refresh operations by mitigating the row hammer effect that occurs in DRAM, and thus to significantly reduce the power consumption of DRAM.

As described above, the present specification has been described with reference to the drawings illustrating one or more embodiments, but it is obvious that the present disclosure is not limited to the embodiments and drawings disclosed in this specification, and various modifications can be made by those skilled in the art within the scope of the technical idea of the present disclosure. In addition, even if the operational or technical effects according to the configuration of the present disclosure are not explicitly described while describing the embodiments of the present disclosure, it is understood that predictable or foreseeable effects by the configuration should also be recognized.

What is claimed is:

1. A semiconductor memory device, comprising:
a substrate;
an element isolation film formed to extend in a vertical direction in the substrate;
a first gate structure formed to extend in the vertical direction in the element isolation film; and
a second gate structure formed to be spaced apart from the element isolation film in a horizontal direction and extend in the vertical direction in the substrate,
wherein a hollow pocket is formed below the first gate structure in the element isolation film.

2. The semiconductor memory device of claim 1, wherein the element isolation film is made of an insulating material.

3. The semiconductor memory device of claim 1, wherein the first gate structure includes a gate electrode of a passing word line constituting a DRAM (Dynamic Random Access Memory).

4. The semiconductor memory device of claim 1, wherein the hollow pocket is surrounded by the element isolation film below the first gate structure.

5. The semiconductor memory device of claim 1, wherein the hollow pocket is filled with a material different from the element isolation film.

6. The semiconductor memory device of claim 1, wherein the hollow pocket is filled with a material having a lower dielectric constant than the element isolation film.

7. The semiconductor memory device of claim 1, wherein the hollow pocket is filled with air.

8. The semiconductor memory device of claim 1, wherein the hollow pocket is formed by:
etching the substrate to form a trench; and
depositing a material constituting the element isolation film on the trench until overhang regions, which are formed at both ends of an entrance of the trench, meet while an inside of the trench is not completely filled.
